(19) United States
(12) Patent Application Publication
(10) Pub. No.: US 2019/0203048 A1
(43) Pub. Date: Jul. 4, 2019

(54) Maleimide Resin Composition, Prepreg, Cured Product Of Same And Semiconductor Device

(71) Applicant: Nippon Kayaku Kabushiki Kaisha, Chiyoda-ku, Tokyo (JP)

(72) Inventors: Kazuki Matsuura, Kita-ku, Tokyo (JP); Masataka Nakanishi, Kita-ku, Tokyo (JP); Kenichi Kuboki, Kita-ku, Tokyo (JP)

(21) Appl. No.: 16/322,514

(22) PCT Filed: Aug. 2, 2017
(86) PCT No.: PCT/JP2017/028091

§ 371 Date: Feb. 1, 2019

(30) Foreign Application Priority Data
Aug. 5, 2016 (JP) 2016-154824

(51) Int. Cl. C08L 79/08; C08K 5/41; C08K 5/23; C08K 5/14; C08J 5/24; C08L 81/06; H01L 23/10

(52) U.S. Cl. CPC C08L 79/08; C08K 5/41; C08K 5/23; C08L 2203/20; C08J 5/24; C08L 81/06; H01L 23/10; C08K 5/14

(57) ABSTRACT

To provide a maleimide resin composition which is curable by a curing process equivalent to that of an epoxy resin and can achieve moldability (curability) at 200° C. or less, heat resistance of 250° C. or more, retention of high thermal stability and high elastic modulus at 250° C., and low dielectric constant/low dielectric loss tangent. A maleimide resin composition including a maleimide compound (A) and a sulfonyl compound (B) containing, in the molecule, a structure represented by the following formula (1):

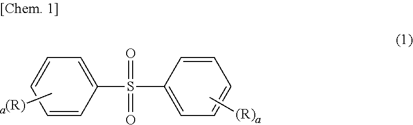

(wherein each of the plurality of R's independently represents an alkenyl group, an alkenyl ether group, a hydrogen tom, a halogen atom, an alkyl group having a carbon number of 1 to 10, a fluoroalkyl group having a carbon number of 1 to 4, a hydroxyl group, an allyloxy group, an amino group, a cyano group, a nitro group, an acyl group, an acyloxy group, a carboxyl group, a tertiary carbon structure-containing group, a cyclic alkyl group, or a glycidyl group; at least one R is an alkenyl group or an alkenyl ether group; and a represents an integer of 1 to 4).

### TECHNICAL FIELD

The present invention relates to a maleimide resin composition, a prepreg, and a cured product thereof. More specifically, the present invention relates to a maleimide resin composition useful for highly reliable semiconductor sealing material application, electric/electronic component insulating material application, various composite material applications including a laminated board (printed-wiring glass fiber-reinforced composite material) and CFRP (carbon fiber-reinforced composite material), various adhesive applications, various coating material applications, structural members, etc., a prepreg, a cured product thereof, and a semiconductor device.

### BACKGROUND ART

An epoxy resin that is a thermosetting resin generally forms, when cured with various curing agents, a cured product excellent in mechanical property, water resistance, chemical resistance, electric property, etc. and utilized in wide range of fields such as adhesive, coating material, laminate, molding material, casting material and sealing material. In recent years, due to expansion of the application field, sophisticated properties are extensively required fir a laminated board carrying electric/electronic components thereon.

In recent years, above all, in association with high functionalization of a power semiconductor, attention is focused as a next-generation device on a wide band-gap device such as SiC (silicon carbide) and GaN (gallium nitride). When an SiC or GaN power semiconductor device is used, space saving due to size reduction, or large loss reduction becomes possible, and therefore, it is demanded to early spread the SiC or GaN device. However, at present, the driving temperature for bringing out the properties of the device is as too high as 200° C. or more, particularly around 250° C., and peripheral materials suffer from insufficient durability. Thus, development of a resin material capable of withstanding the driving conditions above is required.

In such applications, importance is placed not only on heat resistance (Tg) at 200° C. or more, particularly at 250° C., but also on heat stability, and it is supposed to be difficult to use an epoxy resin that starts undergoing thermal decomposition around 200° C. Then, heat-resistant resins such as maleimide resin and benzoxazine resin are aggressively studied, but because of need for molding at a high temperature of 200° C. or more, furthermore at 250° C. the allowable temperature of the molding machine is exceeded, causing a problem with moldability. Moreover, although heat resistance stability at a very high temperature is exhibited for 5% thermal weight loss temperature, these resins relatively early exhibit the initial thermal decomposition temperature, and this is an issue to be solved.

Accordingly, it is urgent need to solve the problems in moldability (curability) at 200° C. or less, heat resistance of 250° C. or more, and thermal stability at 250° C.

In addition, these properties are required also for a printed wiring substrate carrying a semiconductor and are indispensable for the next-generation semiconductor peripheral materials.

Furthermore, the heat resistance property is required increasingly not only for an in-vehicle substrate but also for a substrate for electronic devices typified by smart phone or tablet.

In this field where importance is attached particularly to thickness reduction, each individual substrate mounted inside the device is of course thinned and often exposed to high temperature in each step until mounting. At the time of semiconductor mounting, the layer is exposed to a high temperature of 250° C. or more and if the elastic modulus is low (softened) at 250° or more, the substrate may be deformed. On the other hand, as to the curing temperature, from the problem of oxidation of copper foil surface, molding in the temperature region of exceeding 200° C. particularly 230° C., is difficult. More specifically, in this field, the importance is attached to curability and moldability at 200° C. or less and high elastic modulus (hard) at 250° C.

Incidentally, among others, high-speed communication in such an electronic device is recently attracting attention. An enormous increase in the amount of information/communication in a smart phone or a tablet, to say nothing of a high-frequency substrate, makes it important to how fast a lot of information is transmitted and since high speed communication acts as an important factor for a package substrate, the dielectric properties, particularly, the dielectric loss tangent, are important. While the dielectric loss tangent of the general epoxy resin cured product (resin alone) is 0.02 (measured at 1 (Hz), a dielectric loss constant of ¾ or less, namely, 0.015 or less, particularly 0.010 or less, is required, and it is imperative to develop a material satisfying these properties.

In addition, the fiber-reinforced composite material is composed of a matrix resin and a reinforcement fiber such as carbon fiber, glass fiber, alumina fiber, boron fiber and aramid fiber and in general, is characterized by light weight and high strength. Such a fiber-reinforced composite material is widely used for applications including electric/electronic element insulating materials and laminates (e.g., printed wiring boards, build-up board), for applications as machine tool members typified by aerospace materials such as airframe and wing of passenger aircraft and by robot hand arms or as building and civil engineering repairing materials, and furthermore, for applications as instruments for leisure, such as golf shirt and tennis racket.

Among others, in machine tool members typified by aerospace materials such as airframe and wing of passenger aircraft and by robot hand arms, a carbon fiber-reinforced composite material (hereinafter referred to as “CFRP”) is required to have heat resistance capable of maintaining rigidity in the temperature range from room temperature to about 200° C., mechanical properties, and long-term reliability, that is, sufficiently high thermal decomposition temperature and high elastic modulus at high temperature.

As the matrix resin of the fiber-reinforced composite material, an epoxy resin has heretofore been widely used, but in the application, among others, to an engine part, etc., it is important that the elastic modulus can be maintained also at high temperatures. In this respect, the epoxy resin is insufficient in terms of heat resistance, and a curing system using a maleimide resin is being studied.

However, the maleimide resin alone has poor curability and provides a brittle molded product and therefore, various modifiers have been developed for the improvement of this. As the solution therefor, various modifications are being made, and there are known, for example, a cyanic acid ester-based resin composition in which a modified butadiene-based resin having introduced thereinto a math(acryloyl) group is blended (Patent Document 1), in which a butadiene-acrylonitrile copolymer is added (Patent Document 2), or in which an epoxy resin is further added (Patent Document 3). In these methods, the brittleness of the molded product may be reduced, but all methods above are disadvantageously incapable of avoiding a problem of reduction in the heat resistance and mechanical strength.

On the other hand, a method of modifying the maleic resin with an allyl compound well-known as an additive such as reactive diluent, crosslinker and flame retardant of the maleimide resin is known. For example, there is disclosed a resin composition obtained by heating, melting and mixing 4,4′-diphenylmethanebismaleimide and o,o′-diallylbisphenol A which is liquid at normal temperature, and it is stated that the carbon fiber sheet can be solventlessly impregnated with the resin composition (Patent Document 4). In addition, a maleimide resin composition containing a novolac-type polyphenylmethanemaleimide and o,o′-diallylbisphenol A is disclosed (Patent Document 5).

### CITATION LIST

### Patent Literature

Patent Document 1: JP-A-57-153045 (the term “JP-A” as used herein means an “unexamined published Japanese patent application”)

### Patent Document 2: JP-A-57-153046

### Patent Document 3: JP-A-56-157424

### Patent Document 4: JP-A-5-222186

### Patent Document 5: JP-A-2012-201816

### SUMMARY OF INVENTION

### Technical Problem

However, in Patent Document 4, since the reactivity of o,o′-diallylbisphenol A is low, it is difficult to produce a cured molded body under the curing conditions capable of molding conventional epoxy resin compositions, and a high curing temperature (235 to 250° C.) and a prolonged molding time are necessary, giving rise to a problem that, for example, a burden is placed on the workability and cost and due to the limitation of application parts, the resin composition cannot be used of course for a laminated board and furthermore for semiconductor sealing material application, etc, requiring a short molding cycle.

Accordingly, an object of the present invention is to provide a maleimide resin composition which is curable by a curing process equivalent to that of an epoxy resin and can achieve moldability (curability) at 200° C. or less, heat resistance of 250° C. or more, retention of high thermal stability and high elastic modulus at 250° C., and low dielectric constant/low dielectric loss tangent, a prepreg, a cured product thereof, and a semiconductor device.

### Solution to Problem

As a result of intensive studies to solve the problems above, the present inventors have found that a sulfonyl compound having a specific structure containing an alkenyl group or an alkenyl ether group has excellent reactivity with a maleimide group. The present invention has been accomplished based on this finding.

That is, the present invention relates to:

[1] A maleimide resin composition, comprising:

a maleimide compound (A) and a sulfonyl compound (B) containing, in the molecule, a structure represented by the following formula (1):

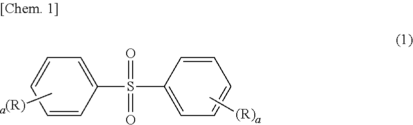

(wherein each of the plurality of R's independently represents an alkenyl group, an alkenyl ether group, a hydrogen atom, a halogen atom, an alkyl group having a carbon number of 1 to 10, a fluoroalkyl group having a carbon number of 1 to 4, a hydroxyl group, an allyloxy group, an amino group, a cyano group, a nitro group, an acyl group, an acylxy group, a carboxyl group, a tertiary carbon structure-containing group, a cyclic alkyl group, or a glycidyl group; at least one R is an alkenyl group or an alkenyl ether group; and a represents an integer of 1 to 4).
[2] The maleimide resin composition according to item [1] above,

wherein the maleimide compound (A) is at least one selected from an aromatic maleimide compound and an aliphatic maleimide compound.

[3] The maleimide resin composition according to item [1] or [2] above,

wherein the sulfonyl compound (B) is a sulfonyl compound represented by the following formula (2):

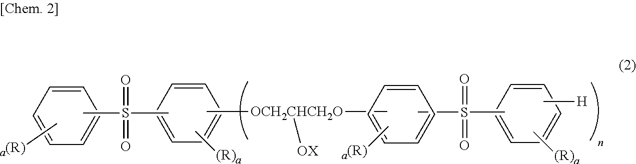

(wherein each of the plurality of R's independently represents an alkenyl group, an alkenyl ether group, a hydrogen atom, a halogen atom, an alkyl group having a carbon number of 1 to 10, a fluoroalkyl group having a carbon number of 1 to 4, a hydroxyl group, an allyloxy group, an amino group, a cyano group, a nitro group, an acyl group, an acyloxy group, a carboxyl group, a tertiary carbon structure-containing group, a cyclic alkyl group, or a glycidyl group; at least one R is an alkenyl group or an alkenyl ether group; each X independently represents a hydrogen atom or a glycidyl group; a represents an integer of 1 to 4; n is from 0 to 10, and the average value thereof represents a real number of 0 to 10).
[4] The maleimide resin composition according to any one of items [1] to [3] above, which contains a modified sulfonyl compound having a molecular structure bonded via an alkylidene bond such as methylene bond, ethylidene bond and propylidene bond, obtained by polymerizing the sulfonyl compound with phenols or naphthols.
[5] The maleimide resin composition according to any one of items [1] to [4] above, further comprising a radical polymerization initiator (C).
[6] The maleimide resin composition according to item [5] above, wherein the radical polymerization initiator (C) is at least one selected from an organic peroxide and an azo compound.
[7] A prepreg, which holds the maleimide resin composition according to any one of items [1] to [6] above on a sheet-like fiber base material and is in a semi-cured state.
[8] A cured product of the maleimide resin composition according to any one of item [1] to [6] above.
[9] A cured product of the prepreg according to item [7] above.
[10] A semiconductor device, which is sealed using the maleimide resin composition according to any one of items [1] to [6].

### Advantageous Effects of Invention

The maleimide resin composition of the present invention has excellent low-temperature curability, and a cured product thereof has heat resistance, water absorption properties, electrical reliability and mechanical strength. Accordingly, these are useful for an electric/electronic component insulating material, a semiconductor sealing material application, various composite materials including a laminated board (e.g., printed wiring board, build-up board) and CFRP, an adhesive, a coating material, etc.

### BRIEF DESCRIPTION OF DRAWINGS

FIG. 1 is a schematic diagram of a lead frame used in Example 22.

FIG. 2 is a schematic diagram of a sealing material created in Example 22.

### DESCRIPTION OF EMBODIMENTS

The maleimide resin composition of the present invention is described below.

The maleimide resin composition of the present invention is characterized by including a maleimide compound (A) and a sulfonyl compound (B) containing, in the molecule, a structure represented by the following formula (1):

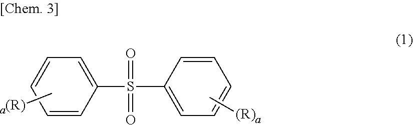

(wherein each of the plurality of R independently represents an alkenyl group, an alkenyl ether group, a hydrogen tom, a halogen atom, an alkyl group having a carbon number of 1 to 10, a fluoroalkyl group having a carbon number of 1 to 4, a hydroxyl group, an allyloxy group, an amino group, a cyano group, a nitro group, an acyl group, an acyloxy group, a carboxyl group, a tertiary carbon structure-containing group, a cyclic alkyl group, or a glycidyl group, at least one R is an alkenyl group or an alkenyl ether group, and a represents an integer of 1 to 4).

As to the sulfonyl compound (B) containing, in the molecule, a structure represented by formula (1) that is a bisphenol S-type compound containing an alkenyl group or an alkenyl ether group, due to the presence of a sulfonyl group functioning as an electron withdrawing group, the density of the highest occupied molecular orbital (HOMO) is considered to be localized to an alkenyl group or an alkenyl ether group, thereby improving reactivity with the compound (A) having a maleimide group functioning as an electron acceptor. Furthermore, the curing speed can be increased by using a radical polymerization initiator.

The maleimide compound (A) used in the present invention is a compound having, in the molecule, one or more maleimide groups represented by the following formula (3):

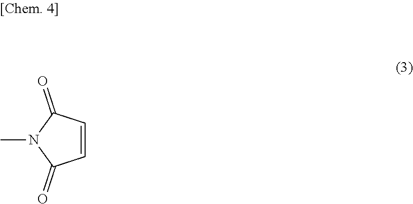

As for the maleimide compound (A) used in the present invention, a known maleimide compound can be used, and examples thereof include an aliphatic/alicyclic maleimide compound and an aromatic maleimide compound.

Specific examples, of the aliphatic/alicyclic maleimide compound include a monofunctional maleimide such as N-methylmaleimide, N-ethylmaleimide, N-propylmaleimide, N-hexylmaleimide, N-cyclohexylmaleimide and maleimidocarboxylic acid, N-2,2′-hydroxyethylmaleimide, N-1-methoxymethylpropylmaleimide, N-1-ethoxymnethylpropylmaleimide, N-1-methoxymethylbutylmaleimide, N,N′-3,6-dioxaoctane-1,8-bismaleimide, N,N′-4,7-dioxanedecane-1,10-bismaleimide, N,N-3,6,9-trioxadodecane-1,11-bismaleimide, N,N′-4,9-dioxadodecane-1,12-bismaleimide, N,N′-4,7,10-trioxatridecane-1,13-bismaleimide, N,N′-7-methyl-4,10-trioxatridecane-1,13-bismaleimide, N,N′-3,6,9,12-tetraoxatetradecane-1,14-bismaleimide, N,N′-3,6,9,12,15-pentaoxaheptadecane-1,17-bismaleinde, and bis(3-N-maleimidopropyl)polytetrahydrofuran.

The aromatic maleimide compound having one maleimide group represented by formula (3) includes a monofunctional maleimide such as N-phenylmaleimide and N-methylphenylmaleimide.

The aromatic maleimide compound having two maleimide groups represented by formula (3) includes, for example, a bifunctional maleimide compound typified by N,N′-methylenebismaleimide, N,N′-trimethylenebismaleimide, N,N′-dodecamethylenebismaleimide, N,N′-(4,4′-diphenylmethane)bismaleimide, 1,4-dimaleimidecyclohexane, isophoronebisurethanebis(N-ethylmaleimide), N,N′—P-phenylenebismaleimide, N,N′-diphenylmethanebismaleimide, N,N′-phenylenebismaleimide. N,N′-diphenyletherbismaleimide, N,N′-diphenylsulfonebismaleimide, N,N′-dicyclohexylmethanebismaleimide, N,N′-xylenebismaleimide, N,N′-tolylenebismaleimide, N,N′-xylylenebismaleimide, N,N′-diphenylcyclohexanebismaleimide, N,N′-dichlorodiphenylmethanebismaleimide, N,N′-diphenylcyclohexanebismaleimide, N,N′-diphenylmethanebismethylmaleimide, N,N′-diphenyletherbismethylmaleimide, N,N′-diphenylsulfonebismethylmaleimide (each including isomers), N,N-ethylenebismaleimide, N,N′-hexamethylenebismaleimide, N,N′-hexamethylenebismaleimide N,N′-dodecamethylenebismaleimide, N,N′-m-xylylenebismaleimide, N,N-p-xylylenedimaleimide, N,N′-1,3-bismethylenecyclohexanebismaleimide, N,N′-1,4-bismethylenecyclohexanebismaleimide, N,N′-2,4-tolylenebismaleimide, N,N′-2,6-tolylenebismaleimide, N,N′-3,3-diphenylmethanebismaleimide, N,N′4,4′-diphenylmethanebismaleimide, 3,3′-diphenylsulfonebismaleimide, 4,4′-diphenylsulfonebismaleimide, N,N′-4,4′-diphenylsulfidebismaleimide, N,N′-p-benzophenonebismaleimide, N,N′-diphenylethanebismaleimide, N,N′-diphenyletherbismaleimide, N,N′-(methylene-ditetrahydrophenyl)bismaleimide, N,N′-(3-ethyl)-4,4-diphenylmethanebismaleimide, N,N′-(3,3′-dimethyl)-4,4′-diphenylmethanebismaleimide, N,N′-(3,3′-diethyl)-4,4′-diphenylmethanebismaleimide, N,N′-(3,3′-dichloro)-4,4′-diphenylmethanebismaleimide, N,N′-tolidinebismaleimide, N,N′-isophoronebismaleimide, N,N′-p,p′-diphenyldimethylsilylbismaleimide, N,N′-benzophenonebismaleimide, N,N′-diphenylpropanebismaleimide, N,N′-naphthalenebismaleimide, N,N′-m-phenylenebismaleimide, N,N′-4,4′-(1,1-diphenyl-cyclohexane)-bismaleimide, N,N′-3,5-(1,2,4-triazole)-bismaleimide, N,N′-pyridine-2,6-diylbismaleimide, N,N′-5-methoxy-1,3-phenylenebismaleimide, 1,2-bis(2-maleimidoethoxy)ethane, 1,3-bis(3-maleimidopropoxy)propane, N,N′-4,4-diphenylmethane-bis-dimethylmaleimide, N,N′-hexamethylene-bis-dimethylmaleimide, N,N′-4,4′-(diphenylether)-bis-dimethylmaleimide, N,N′-4,4′-(diphenylsulfone)-bis-dimethylmaleimide, N,N′-bismaleimide of N,N′-4,4′-(diamino)-triphenylphosphate, etc.

The aromatic maleimide compound having three or more maleimide groups represented by formula (3) includes a polyfunctional maleimide compound obtained by the reaction of a reaction product (a polyamine compound) of aniline and formalin, 3,4,4′-triaminodiphenylmethane, triaminophenol, etc., with maleic anhydride.

Examples thereof include a maleimide compound obtained by the reaction of tris-(4-aminophenyl)-phosphate, tris(4-aminophenyl)-phosphate, tris(4-aminophenyl)-thiophosphate with maleic anhydride, 2,2-bis[4-(4-maleimidophenoxy)phenyl]propane, 2,2-bis[3-methyl-4-(4-maleimidophenoxy)phenyl]propane, 2,2-bis[3-chloro-4-(4-maleimidophenoxy)phenyl]propane, 2,2-bis[3-bromo-4-(4-maleimidophenoxy)phenyl]propane, 2,2-bis[3-ethyl-4-(4-maleimidophenoxy)phenyl]propane, 2,2-bis[3-propyl-4-(4-maleimidophenoxy)phenyl]propane, 2,2-bis[3-isopropyl-4-(4-maleimidophenoxy)phenyl]propane, 2,2-bis[3-butyl-4-(4-maleimidophenoxy)phenyl]propane, 2,2-bis[3-secondary butyl-4-(4-maleimidophenoxy)phenyl]propane, 2,2-bis[3-methoxy-4-(4-maleimidophenoxy)phenyl]propane, 1,1-bis[4-(4-maleimidophenoxy)phenyl]ethane, 1,1-bis[3-methyl-4-(4-maleimidophenoxy)phenyl]ethane, 1,1-bis[3-chloro-4-(4-maleimidophenoxy)phenyl]ethane, 1,1-bis[3-bromo-4-(4-maleimidophenoxy)phenyl]ethane, bis[4-(4-maleimidophenoxy)phenyl]methane, bis[3-methyl-4-(4-maleimidophenoxy)phenyl]methane, bis[3-chloro-4-(4-maleimidophenoxy)phenyl]methane, bis[3-bromo-4-(4-maleimidophenoxy)phenyl]methane, 1,1,1,3,3,3-hexafluoro-2,2-bis[4-(4-maleimidophenoxy)phenyl]propane, 1,1,1,3,3,3-hexachloro-2,2-bis[4-(4-maleimidophenoxy)phenyl]propane, 3,3-bis[4-(4-maleimidophenoxy)phenyl]pentane, 1,1-bis[4-(4-maleimidophenoxy)phenyl]propane, 1,1,1,3,3,3-hexafluoro-2,2-bis[3,5-dimethyl-(4-maleimidophenoxy)phenyl]propane, 1,1,1,3,3,3-hexafluoro-2,2-bis[3,5-dibromo-(4-maleimidophenoxy)phenyl]propane, 1,1,1,3,3,3-hexafluoro-2,2-bis-[3,5-methyl-4-maleimidophenoxy)phenyl]propane, a prepolymer having an N,N′-bismaleimide skeleton at the terminal obtained by the addition of such an N,N′-bismaleimide compound and diamines, and a maleimidated or methylmaleimidated compound of an aniline-fortalin polycondensate.

One of these maleimide compounds may be used alone, or two or more thereof may be used in combination. It is also possible to use an aromatic maleimide compound and an aliphatic maleimide compound in combination.

In the present invention, particularly in view of heat resistance (glass transition point) and/or modulus, an aromatic maleimide is preferred, and its combination with a maleimide having two or more functional groups per molecule is preferred.

The sulfonyl compound (B) used in the present invention is a compound containing, in the molecular, a structure represented by the following formula (1):

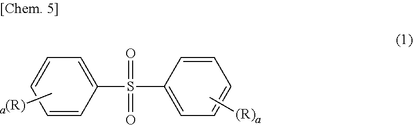

(wherein each of the plurality of R independently represents an alkenyl group, an alkenyl ether group, a hydrogen tom, a halogen atom, an alkyl group having a carbon number of 1 to 10, a fluoroalkyl group having a carbon number of 1 to 4, a hydroxyl group, an allyloxy group, an amino group, a cyano group, a nitro group, an acyl group, an acyloxy group, a carboxyl group, a tertiary carbon structure-containing group, a cyclic alkyl group, or a glycidyl group, at least one R is an alkenyl group or an alkenyl ether group, and a represents an integer of 1 to 4).

The component (B) is used as an aromatic liquid reactive diluent for the maleimide group-containing compound (A). The bisphenol S structure exhibits excellent reactivity with the maleimide group-containing compound, relative to the bisphenol A structure. This is considered to be attributable to the electron withdrawing property of the sulfonyl group as described above.

The alkenyl group or alkenyl ether group in the formula includes a vinyl group, a styryl group, an allyl group, a substituted allyl group, a propenyl group, a substituted propenyl group, a vinyl ether group, an allyl ether group, and a methallyl ether group.

The substituent other than the alkenyl group or alkenyl ether group in the formula includes a hydrogen atom, a halogen atom, an alkyl group having a carbon number of 1 to 10, a fluoroalkyl group having a carbon number of 1 to 4, a hydroxyl group, an allyloxy group, an amino group, a cyano group, a nitro group, an acyl group, an acyloxy group, a carboxyl group, a tertiary carbon structure-containing group, a cyclic alkyl group, a glycidyl group, and a combination thereof.

In the formula, a is from 1 to 4, preferably 1 or 2.

The sulfonyl compound (B) containing, in the molecular, a structure represented by formula (1) is preferably a compound represented by the following formula (2):

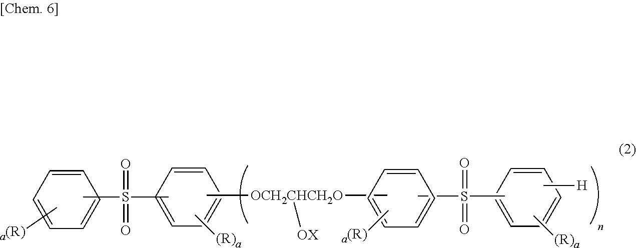

(wherein R has one or more alkenyl groups or alkenyl ether groups and represents, as the substituent other than those, a hydrogen atom, a halogen atom, an alkyl group having a carbon number of 1 to 10, a fluoroalkyl group having a carbon number of 1 to 4, a hydroxyl group, an allyloxy group, an amino group, a cyano group, a nitro group, an acyl group, an acyloxy group, a carboxyl group, a tertiary carbon structure-containing group, a cyclic alkyl group, or a glycidyl group, each X independently represents a hydrogen atom or a glycidyl group, a represents an integer of 1 to 4, n is from 0 to 10, and the average value thereof represents a real number of 0 to 10).

In formula (2), n is from 0 to 10, preferably from 0 to 5, and the average value of n is from 0 to 10, preferably from 0 to 5.

Specific examples of the sulfonyl compound (B) containing a structure represented by formula (1) or being represented by formula (2) include 2,2′-diallyl-4,4′-sulfonyldiphenol, 2-allyl-2′-propenyl-4,4′-sulfonyldiphenol, 2,2′-dipropenyl-4,4′-sulfonyldiphenol, 2,2′-diallyl-6,6′-sulfonyldiphenol, 2-allyl-2′-propenyl-6,6′-sulfonyldiphenol, 2,2′-dipropenyl-6,6′-sulfonyldiphenol, 2,2′-diallyl-4,4′-sulfonyldiglycidyl ether, 2-allyl-2′-propenyl-4,4′-sulfonyldiglycidyl ether, 2,2′-dipropenyl-4,4′-sulfonyldiglycidyl ether, 2,2′-diallyl-6,6′-sulfonyldidiglycidyl ether, 2-allyl-2′-propenyl-6,6′-sulfonyldiglycidyl ether, and 2,2′-dipropenyl-6,6′-sulfonyldiglycidyl ether.

The softening point of the component (B) is usually from 60 to 130° C., preferably from 70 to 120° C., more preferably from 80 to 120° C.

The maleimide resin composition of the present invention contains at least the component (A) and the component (B), and the content of the component (B) per 100 parts by weight of the component (A) is 1 part by weight or more, preferably 10 parts by weight or more, and 200 parts by weight or less, preferably 100 parts by weight or less.

If the content of the component (B) is smaller than the range above, the viscosity of the composition rises to increase the non-uniformity of the composition, and this may lead to poor moldability. If the content of the component (13) exceeds the range above, the glass transition temperature of the cured product may be lowered.

In addition, the component (A) and the component (B) are blended such that the ratio (weight ratio) of the component (A) to the total of these components becomes preferably from 0.5 to 0.9, more preferably from 0.5 to 0.8. If the ratio of the component (A) to the total of the component (A) and the component (B) is less than the lower limit above, the glass transition temperature of the cured product excessively drops, and the weight during processing at 300° C. for 24 hours extremely decreases, whereas if the ratio exceeds the upper limit above, the viscosity of the composition greatly rises or the composition becomes significantly non-uniform, which may lead to poor moldability.

The maleimide resin composition of the present invention may contain a radical polymerization initiator (C), other than the component (A) and the component (B). In the maleimide resin composition, the radical polymerization initiator (C) is used for the purpose of promoting the reaction of an alkenyl group or an alkenyl ether group with a maleimide group.

The usable radical polymerization initiator (C) is not particularly limited but includes an organic peroxide and an azo compound, with an organic peroxide being preferred.

The organic peroxide includes, for example, methyl ethyl ketone peroxide, cyclohexane peroxide, 3,3,5-trimethylcyclohexanone peroxide, methylcyclohexanone peroxide, methylacetoacetate peroxide, acetylacetone peroxide, 1,1-bis(tert-butylperoxy)-3,3,5-trimethylhexane, 1,1-bis(tert-butylperoxy)cyclohexane, 2,2-bis(tert-butylperoxy)octane, n-butyl-4,4-bis(tert-butylperoxy)valerate, 2,2-bis(tert-butylperoxy)butane, tert-butyl hydroperoxide, cumene hydroperoxide, diisopropylbenzene hydroperoxide, p-menthane hydroperoxide, 2,5-dimethylhexane-2,5-dihydroperoxide, 1,1,3,3-tetramethylbutyl hydroperoxide, di-tert-butyl peroxide, tert-butylcumyl peroxide, dicumyl peroxide, α,α′-bis(tert-butylperoxy-m-isopropyl)benzene, 2,5-dimethyl-2,5-bis(tert-butylperoxy)hexane, 2,5-dimethyl-2,5-bis(tert-butylperoxy)hexyne, acetyl peroxide, isobutyl peroxide, octanoyl peroxide, decanoyl peroxide, benzoyl peroxide, lauroyl peroxide, 3,5,5-trimethylhexanoyl peroxide, succinic acid peroxide, 2,4-dichlorobenzoyl peroxide, m-toluoyl peroxide, diisopropyl peroxydicarbonate, di-2-ethylhexyl peroxydicarbonate, di-n-propyl peroxydicarbonate, bis(4-tert-butylcyclohexyl)peroxydicarbonate, dimyristyl peroxydicarbonate, di-2-ethoxyethyl peroxydicarbonate, dimethoxyisopropyl peroxydicarbonate, di(3-methyl-3-methoxybutyl)peroxydicarbonate, diallyl peroxydicarbonate, tert-butyl peroxyacetate, tert-butyl peroxyisobutyrate, tert-butyl peroxypivalate, tert-butyl peroxyneodecanoate, cumyl peroxyneodecanoate, tert-butylperoxy-2-ethylhexanoate, tert-butylperoxy-3,5,5-trimethylhexanoate, tert-butyl peroxylaurate, tert-butyl peroxybenzoate, di-tert-butyl peroxyisophthalate, 2,5-dimethyl-2,5-di(benzoylperoxy)hexane, tert-butyl peroxymaleic acid, tert-butyl peroxyisopropylcarbonate, cumyl peroxyoctoate, tert-hexyl peroxyneodecanoate, tert-hexyl peroxypivalate, tert-butyl peroxyneohexanoate, acetylcyclohexylsulfonyl peroxide, and tert-butyl peroxyallylcarbonate.

Of these organic peroxides, those undergoing decomposition and radical generation at a temperature of 120° C. or more are preferred, and as such an organic peroxide compound, benzoyl peroxide, diisopropyl peroxycarbonate, lauroyl peroxide, dicumyl peroxide, methyl ethyl ketone peroxide, and di-tert-butyl peroxide are preferred.

The azo compound includes azoisobutylnitrile, etc. Among others, a compound that is activated by heat is suitably used. One of these compounds may be used alone, or two or more thereof may be used in combination.

The amount of the polymerization initiator as the component (C) is usually from 0.001 to 10 parts by weight, preferably from 0.01 to 5 parts by weight, more preferably from 0.01 to 3 parts by weight, still more preferably from 0.01 to 1 part by weight, per 100 parts by weight of the component (A).

If the amount of the component (C) is less than the range above, the polymerization promoting effect cannot be sufficiently obtained, giving rise to a curing failure, whereas if the amount is too large, this may adversely affect the curing and physical properties of the resin composition. For this reason, the component is added in an amount of 0.001 to 10 wt % per 100 parts by weight of the component (A).

In the maleimide resin composition of the present invention, a curing accelerator other than the radical polymerization initiator may be used or may be used in combination, if desired. The curing accelerator used includes imidazoles such as 2-methylimidazole, 2-ethylimidazole, 2-phenylimidazole, 2-ethyl-4-methylimidazole, 2-undecylimidazole and 1-cyanoethyl-2-ethyl-4-methylimidazole amines such as triethylamine, triethylenediamine, 2-(dimethylaminomethyl)phenol, 1,8-diazabicyclo(5,4,0)undecene-7, tris(dimethylaminomethyl)phenol and benzyldimethylamine, phosphines such as triphenylphosphine, tributylphosphine and trioctylphosphine, an organic metal salt such as tin octylate, zinc octylate, dibutyltin dimaleate, zinc naphthenate, cobalt naphthenate and tin oleate, a metal chloride such as zinc chloride, aluminum chloride and tin chloride, other organometallic compounds, etc. and includes an organic peroxide such as benzoyl peroxide, dicumyl peroxide, methyl ethyl ketone peroxide and tert-butyl perbenzoate. If the amount of the curing accelerator is too small, a curing failure may be caused, and if it is too large, this may adversely affect the curing and physical properties of the resin composition. Accordingly, the curing accelerator is added in an amount of preferably from 0.01 to 20 wt %, more preferably from 0.01 to 10 wt %, relative to the maleimide resin.

On the other hand, the radical polymerization accelerator exerts a polymerization accelerating effect on both of the components (A) and (B) used in the present invention but forms an unstable oxygen-carbon bond at some component terminals. This oxygen-carbon bond burns at high temperatures to cause thermal weight loss and therefore, in a cured product obtained from a polymaleimide-based composition using only a radical polymerization accelerator as the polymerization accelerator, when it is placed under high temperature condition for a long period of time, the thermal weight loss rate may be increased. Accordingly, enhancement of heat resistance and suppression of the thermal weight loss can be achieved by using an anionic polymerization accelerator and a radical polymerization accelerator in combination and making up for respective faults while utilizing advantages thereof. The catalyst added is preferably an anionic polymerization agent, among others.

In the maleimide resin composition of the present invention, a cyanate ester compound can also be blended, in addition to the components (A) to (C). As the cyanate ester compound that can be blended in the maleimide resin composition of the present invention, a conventionally known cyanate ester compound can be used. Specific examples of the cyanate ester compound include, but are not limited to, cyanate ester compounds obtained by reacting a polycondensate of phenols and various aldehydes, a polymerization product of phenols and various diene compounds, a polycondensate of phenols and ketones, a polycondensate of bisphenols and various aldehydes, etc. with a cyanogen halide. One of these may be used alone, or two or more thereof may be used in combination.

In addition, a cyanate ester compound produced by the synthesis method described in JP-A-2005-264154 is excellent in low hygroscopicity, flame retardancy and dielectric properties and is therefore particularly preferable as the cyanate ester compound.

Furthermore, in the maleimide resin composition of the present invention, known additives may be blended, if desired. Specific examples of the additive that can be used include an epoxy resin, a curing agent for epoxy resin, a polybutadiene and its modification product, a modified acrylonitrile copolymer, a polyphenylene ether, a polystyrene, a polyethylene, a polyimide, a fluororesin, a maleimide-based compound, a cyanate ester-based compound, a silicone gel, a silicone oil, an inorganic filler such as silica, alumina, calcium carbonate, quartz powder, aluminum powder, graphite, talc, clay, iron oxide, titanium oxide, aluminum nitride, asbestos, mica and glass powder, a surface treating agent for filler, such as silane coupling agent, a release agent, and a colorant such as carbon black, phthalocyanine blue and phthalocyanine green. The blending amount of such an additive is preferably 1.000 parts by weight or less, more preferably 700 parts by weight or less, per 100 parts by weight of the maleimide resin composition.

The preparation method of the maleimide resin composition of the present invention is not particularly limited, and respective components may be uniformly mixed, or a prepolymer may be formed. For example, the maleimide resin (A) and the alkenyl group- or alkenyl ether group-containing sulfonyl group (B), which are used in the present invention, may be heated in the presence or absence of a catalyst and in the presence or absence of a solvent to form a prepolymer. A prepolymer may also be formed by additionally adding, if desired, a curing agent such as amine compound, cyanate ester compound, phenol resin and acid anhydride compound, and other additives. The mixing of respective components or the formation of a prepolymer uses, in the absence of solvent, for example, an extruder, a kneader or a roller, and uses, in the presence of solvent, for example, a reaction oven equipped with a stirring device.

The maleimide resin composition of the present invention may be formed as a varnish-like composition (hereinafter, simply referred to as varnish) by adding an organic solvent. A prepreg obtained by dissolving, if desired, the maleimide resin composition of the present invention in a solvent such as toluene, xylene, acetone, methyl ethyl ketone, methyl isobutyl ketone, dimethylformamide, dimethylacetamide and N-methylpyrrolidone to make an epoxy resin composition varnish, impregnating a base material such as carbon fiber, glass fiber, carbon fiber, polyester fiber, polyamide fiber, alumina fiber and paper with the varnish, and heating and drying the resin composition is subjected to heat press molding, and a cured product of the maleimide resin composition of the present invention can thereby be fabricated. The solvent here is used in an amount accounting for usually from 10 to 70 wt %, preferably from 15 to 70 wt %, of the mixture of the maleimide resin composition of the present invention and the solvent. Furthermore, in the case of a liquid composition, a cured product of the maleimide resin composition containing a carbon fiber can also be directly obtained, for example, by RTM method.

In addition, the maleimide rosin composition of the present invention can be used as a modifier of a film-type composition. Specifically, the composition can be used in the case of enhancing the flexibility, etc. in B-stage. The film-type composition can be obtained as a sheet-like adhesive by coating a release film with the epoxy resin composition of the present invention as the above-described epoxy resin composition varnish, removing the solvent under heating, and then performing B-staging. The sheet-like adhesive obtained can be used as an interlayer insulating layer in a multilayer substrate, etc.

The prepreg of the present invention can be obtained by heating/melting the maleimide resin composition of the present invention to reduce the viscosity, and impregnating a reinforcement fiber such as glass fiber, carbon fiber, polyester fiber, polyamide fiber and alumina fiber with the varnish.

The prepreg of the present invention can also be obtained by impregnating a reinforcement fiber with the varnish, and then heating and drying the varnish.

The method for impregnating such a reinforcement fiber with the maleimide resin composition is also not particularly limited, but a method not using a solvent is preferred and therefore, a hot-melt method of heating the maleimide resin composition of the present invention at 60 to 110° C. and achieving impregnation in a flowable state is preferred.

The ratio of the polymaleimide-based composition in the obtained prepreg (a product obtained by impregnating a reinforcement fiber with the maleimide resin composition) may vary depending on the form of the reinforcement fiber but is usually from 20 to 80 wt %, preferably from 25 to 65 wt %, more preferably from 30 to 50 wt %. If the ratio of the polymaleimide resin composition exceeds this range, the ratio of the reinforcement fiber relatively decreases, failing in obtaining a sufficient reinforcing effect, and conversely, if the ratio of the polymaleimide resin composition is small, the moldability is impaired.

The prepreg can be cured by a known technique to form a final molded article. For example, a prepreg may be stacked, pressurized at 2 to 10 kgf/cm² in an autoclave, and heated/cured at 150 to 200° C. for 30 minutes to 3 hours to obtain a molded body, but in order to more enhance the heat resistance, a post-cure treatment may be performed for 1 to 12 hours while raising the temperature step by step in the temperature range of 180 to 280° C. to fabricate a fiber-reinforced composite molded article.

A laminated board can be obtained by cutting the prepreg above into a desired shape, laminating it with a copper foil, etc., if desired, and then heating and curing the epoxy resin composition for laminated board while applying a pressure to the laminate by a press molding method, an autoclave molding method, a sheet winding molding method, etc.

Furthermore, a multilayer circuit board can be obtained by repeating an operation of forming a circuit on a laminated board having stacked on the surface thereof a copper foil and stacking thereon a prepreg, a copper foil, etc.

The maleimide resin composition of the present invention, a prepreg, or a cured product thereof, among others, a cured product of the prepreg, is useful particularly for a robot hand for transporting a liquid crystal glass substrate. However, the application of the cured product of the present invention is not limited to the robot hand for transporting a liquid crystal glass substrate but can be widely applied to other members requiring light weight, high strength and high heat resistance, such as disc for transporting a silicon wafer, aerospace member and automobile engine member.

The present invention is described more specifically below by referring to Examples and in the following, unless otherwise indicated, “parts” indicates “parts by weight”. Incidentally, the present invention is not limited to these Examples.

Various analysis methods used in Examples are described below.

### Example

The present invention is described in greater detail below by referring to Examples. However, the present invention is not limited to these Examples. In Examples, the epoxy equivalent, melt viscosity, softening point, and total chlorine concentration were measured under the following conditions.

Epoxy equivalent: Measured by the method in conformity with JIS K-7236.

Melt viscosity: Melt viscosity in the cone-plate method at 150° C.

Softening point: Measured by the method in conformity with JIS K-7234.

Proportion of propenyl group in all R's in formula (1) or (2): Measured by NMR.

### Synthesis Example 1

165 Parts by weight of 2,2′-diallyl-4,4′-sulfonyldiphenol (produced by Nippon Kayaku Co., Ltd., ARM-019, B1) and 200 parts by weight of methanol were charged into a reactor and after stirring and dissolving the mixture, 105 parts by weight of granular potassium hydroxide (purity: 85%) was added. Following the addition, methanol was distilled off under heating, and the reaction was allowed to proceed for 4 hours while keeping the inner temperature at 100° C. After neutralization with hydrochloric acid, 330 parts by weight of methyl isobutyl ketone was added, and water washing was repeated. Subsequently, methyl isobutyl ketone was distilled off from the oil layer under heating and reduced pressure to obtain 161 parts by weight of 2,2-dipropenyl-4,4′-sulfonyldiphenol. The softening point of the obtained 2,2′-dipropenyl-4,4′-sulfonyldiphenol (B2) was 81° C.

### Synthesis Example 2

165 Parts by weight of 2,2′-dipropenyl-4,4′-sulfonyldiphenol (B2) obtained in Synthesis Example 1, 510 parts by weight of epichlorohydrin and 130 parts by weight of dimethylsulfoxide were charged into a reactor and after heating, stirring and dissolving the mixture, 41 parts by weight of flaky sodium hydroxide was continuously added over 1.5 hours while keeping the temperature at 45° C. After the completion of addition of sodium hydroxide, the reaction was allowed to proceed at 45° C. for 2 hours and at 70° C. for 1 hour. Subsequently, excess epichlorohydrin and dimethylsulfoxide were distilled off under heating and reduced pressure, and 330 parts by weight of methyl isobutyl ketone was added to the residue to dissolve the residue. Byproduct salts were removed by water washing from the resulting methyl isobutyl ketone solution, and 10 parts by weight of an aqueous 30% sodium hydroxide solution was then added thereto. After the reaction was allowed to proceed at 70° C. for 1 hour, water washing of the reaction solution was repeated until the washing liquid became neutral. Thereafter, methyl isobutyl ketone was distilled off from the oil layer under heating and reduced pressure to obtain 207 parts by weight of an epoxy group-containing sulfonyl compound (B3). In the obtained epoxy group-containing sulfonyl compound (B3), the epoxy equivalent was 236 g/eq., the softening point was 64° C., the melt viscosity was 0.09 Pa·s, and the proportion of propenyl group in all R's in formula (2) was 100%.

### Synthesis Example 3

165 Parts by weight of 2,2′-diallyl-4,4′-sulfonyldiphenol (B1), 510 parts by weight of epichlorohydrin and 130 parts by weight of dimethylsulfoxide were charged into a reactor and after heating, stirring and dissolving the mixture, 41 parts by weight of flaky sodium hydroxide was continuously added over 1.5 hours while keeping the temperature at 45° C. After the completion of addition of sodium hydroxide, the reaction was allowed to proceed at 45° C. for 2 hours and at 70° C. for 1 hour. Subsequently, excess epichlorohydrin and dimethylsulfoxide were distilled off under heating and reduced pressure, and 330 parts by weight of methyl isobutyl ketone was added to the residue to dissolve the residue. Byproduct salts were removed by water washing from the resulting methyl isobutyl ketone solution, and 10 parts by weight of an aqueous 30% sodium hydroxide solution was then added thereto. After the reaction was allowed to proceed at 70° C. for 1 hour, water washing of the reaction solution was repeated until the washing liquid became neutral. Thereafter, methyl isobutyl ketone was distilled off from the oil layer under heating and reduced pressure to obtain 207 parts by weight of an epoxy group-containing sulfonyl compound (B4). In the obtained epoxy group-containing sulfonyl compound (B4), the epoxy equivalent was 229 g/eq., the softening point was 64° C., the melt viscosity was 0.09 Pa-s, and the proportion of propenyl group in all R's in formula (2) was 100%.

### Synthesis Example 4

Into a flask equipped with a thermometer, a cooling tube, a Dean-Stark azeotropic distillation trap and a stirrer, 372 parts of aniline and 200 parts of toluene were charged, and 146 parts of 35% hydrochloric acid was added dropwise at room temperature for 1 hour. After the completion of dropwise addition, water and toluene produced by azeotropy when heated were subjected to cooling/liquid separation. Thereafter, only toluene as an organic layer was returned to the system, followed by dehydration. Subsequently, 125 parts of 4,4′-bis(chloromethyl)biphenyl was added over 1 hour while keeping the system at 60 to 70° C., and the reaction was allowed to proceed at the same temperature for 2 hours. After the completion of reaction, toluene was distilled off while raising the temperature, and the inside of the system was set at 195 to 200° C. The reaction was allowed to proceed at this temperature for 15 hours, and 330 parts of an aqueous 30% sodium hydroxide solution was then slowly added dropwise under cooling so as not to allow for vigorous reflux inside the system. The toluene distilled off at the time of temperature rise was returned inside the system at 80° C. or less and left standing still at 70 to 80° C. The water layer as the lower layer after separation was removed, and water washing of the reaction solution was repeated until the washing liquid became neutral. Furthermore, excess aniline and toluene were distilled off from the oil layer under heating and reduced pressure (200° C., 0.6 KPa) by means of a rotary evaporator to obtain 173 parts of aromatic amine resin. The content of diphenylamine in the aromatic amine resin was 2.0%.

The obtained resin was again placed in a rotary evaporator and instead of steam blowing, water was added dropwise little by little under heating and reduced pressure (200° C., 4 KPa). As a result, 166 parts of aromatic amine resin (at) was obtained. In the obtained aromatic amine resin (a1), the softening point was 56° C., the melt viscosity was 0.035 Pa·s and the content of diphenylamine was 0.1% or less.

### Synthesis Example 5

Into a flask equipped with a thermometer, a cooling tube, a Dean-Stark azeotropic distillation trap and a stirrer, 147 parts of maleic anhydride and 300 parts of toluene were charged, and water and toluene produced by azeotropy when heated were subjected to cooling/liquid separation. Thereafter, only toluene as an organic layer was returned to the system, followed by dehydration. Subsequently, a resin solution prepared by dissolving 195 parts of aromatic amine resin (a1) obtained in Synthesis Example 4 in 195 parts of N-methyl-2-pyrrolidone was added dropwise over 1 hour while keeping the inside of the system at 80 to 85° C. After the completion of dropwise addition, the reaction was allowed to proceed at the same temperature for 2 hours, and 3 parts of p-toluenesulfonic acid was added. Condensed water and toluene produced by azeotropy under reflux conditions were subjected to cooling/liquid separation, only toluene as an organic layer was returned to the system, and the reaction was allowed to proceed for 20 hours while performing dehydration. After the completion of reaction, 120 parts of toluene was added, and water washing was repeated to remove p-toluenesulfonic acid and excess maleic anhydride. The residue was heated to remove water by azeotropy from the system and subsequently, the reaction solution was concentrated to obtain a resin solution containing 70% of maleimide resin (A1).

### Synthesis Example 6

To a flask equipped with a stirrer, a reflux condenser tube and a stirring device, 720 pans by mass of dimethylsulfoxide, 540 parts by mass of 2,2′-diallyl-4,4′-sulfonyldiphenol (B1 hydroxyl equivalent: 263 g/eq. softening point: 65° C.), and 280 parts by mass (1.2 molar equivalents per molar equivalent of hydroxyl group of the phenol resin) of allyl chloride (purity 99%, produced by Tokyo Chemical Industry Co., Ltd.) were added and dissolved by raising the temperature to 27° C. Subsequently, 134 parts by mass of an aqueous 46.3 mass % sodium hydroxide solution was slowly added so as not to exceed an inner temperature of 35° C., and 70.0 parts by mass (1,1 molar equivalents per molar equivalent of hydroxyl group of the phenol resin) of flaky sodium hydroxide (purity: 99%, produced by Tosoh Corporation) was then added over 60 minutes. Immediately, the reaction was allowed to proceed at 30 to 35° C. for 4 hours, at 40 to 45° C. for 1 hour, and at 55 to 60° C. for 1 hour. At this time, the reaction was traced using HPLC, and disappearance of the raw material phenol resin and no increase in the intermediate peak between peaks of n=1 form and n=2 form were confirmed.

After the completion of reaction, water, dimethylsulfoxide, etc. were distilled off by means of a rotary evaporator, and the residue was neutralized by adding 30 parts by mass of acetic acid. Furthermore, 700 parts by mass of methyl isobutyl ketone was added, and water washing was repeated. After confirming that the aqueous layer was neutralized, solvents were distilled off from the oil layer under reduced pressure while bubbling nitrogen by use of a rotary evaporator to obtain 629 parts by mass of an allyl ether group-containing sulfonyl compound (B5) of formula (2) where n=2.0.

### Synthesis Example 7

To a flask equipped with a stirrer, a reflux condenser tube and a stirring device, 720 parts by mass of dimethylsulfoxide, 540 parts by mass of 2,2′-diallyl-4,4′-sulfonyldiphenol (B1 hydroxyl equivalent: 263 g/eq. softening point: 65° C.), and 299 parts by mass (1.1 molar equivalents per molar equivalent of hydroxyl group of the phenol resin) of methallyl chloride (purity 99%, produced by Tokyo Chemical Industry Co., Ltd.) were added and dissolved by raising the temperature to 27° C. Subsequently, 134 parts by mass of an aqueous 46.3 mass % sodium hydroxide solution was slowly added so as not to exceed an inner temperature of 35° C., and 70.0 parts by mass (1.1 molar equivalents per molar equivalent of hydroxyl group of the phenol resin) of flaky caustic soda (purity: 99%, produced by Tosoh Corporation) was then added over 60 minutes. Immediately, the reaction was allowed to proceed at 30 to 35° C. for 4 hours, at 40 to 45° C. for 1 hour, and at 55 to 60° C. for 1 hour.

After the completion of reaction, water, dimethylsulfoxide, etc. were distilled off by means of a rotary evaporator, and the residue was neutralized by adding 30 parts by mass of acetic acid. Furthermore, 700 parts by mass of methyl isobutyl ketone was added, and water washing was repeated. After confirming that the aqueous layer was neutralized, solvents were distilled off from the oil layer under reduced pressure while bubbling nitrogen by use of a rotary evaporator to obtain 630 parts by mass of a methallyl ether group-containing sulfonyl compound (B6) of formula (2) where n=2.0.

### Example 1

63 Parts by weight of maleimide resin (A1) obtained in Synthesis Example S and 35 parts by weight of 2,2′-diallyl-4,4′-sulfonyldiphenol (B1) were blended and kneaded at 150° C., and 2 parts by weight of dicumyl peroxide (DCP, produced by Kayaku Akzo Corporation. C1) as a curing accelerator was then blended and kneaded at 80° C. to obtain a maleimide resin composition. MDSC measurement of the obtained maleimide resin composition was performed so as to observe its exothermic behavior. The results are shown in Table 1.

### Example 2

63 Parts by weight of maleimide resin (A1) obtained in Synthesis Example 5 and 35 parts by weight of sulfonium compound (B2) obtained in Synthesis Example 1 were blended and kneaded at 150° C., and 2 parts by weight of dicumyl peroxide (C1) as a curing accelerator was then blended and kneaded at 80° C. to obtain a maleimide resin composition. MDSC measurement of the obtained maleimide resin composition was performed so as to observe its exothermic behavior. The results are shown in Table 1.

### Comparative Example 1

63 Parts by weight of maleimide resin (A1) obtained in Synthesis Example 5 and 35 parts by weight of o,o′-diallylbisphenol A (b1) were blended and kneaded at 150° C. and 2 parts by weight of dicumyl peroxide (C1) as a curing accelerator was then blended and kneaded at 80° C. to obtain a maleimide resin composition. MDSC measurement of the obtained maleimide resin composition was performed so as to observe its exothermic behavior. The results are shown in Table 1.

Curing Exotherm:

The curing exothermic onset temperature, curing exothermic peak top temperature and exothermic end temperature were measured by modulated DSC (MDSC) measurement.

Analysis Conditions:

Analysis mode: MDSC measurement

Measuring instrument: Q2000, manufactured by TA-instruments

Temperature rise rate: 3° C./min

TABLE 1

| | | Exam- | | Comparative |
|---|---|---|---|---|
| | Unit | ple 1 | Example 2 | Example 1 |
| Exothermic onset temperature | ° C. | 132 | 112 | 123 |
| Exothermic peak top | ° C. | 160 | 143 | 156 |
| Exothermic end temperature | ° C. | 189 | 171 | 187 |
| Exothermic onset temperature | ° C. | — | — | 191 |
| Exothermic peak top | ° C. | — | — | 223 |
| Exothermic end temperature | ° C. | — | — | 276 |
| Number of peaks | | 1 | 1 | 2 |
| Curability at 180° C. | | ∘ | ∘ | x |

It is seen from Table 1 that compared with the maleimide resin composition using bis A-type allylphenol, the maleimide resin composition of the present invention completes its curing at a relatively low temperature of 200° C. or less and has therefore excellent curability. This suggests that an electron-withdrawing sulfonyl group is conjugated to adjacent carbon and curability of the alkenyl or alkenyl ether group is thereby imparted. In addition, since the exothermic onset temperature is 100° C. or more, it is expected that an increase in the viscosity during kneading at 100° C. or more can be suppressed.

Furthermore, since the gel time at 175° C. is about 30 seconds, the composition has curability comparable to that of the epoxy resin/phenol curing system and is therefore believed to be usable also in the semiconductor scaling material field requiring, among others, the speed of the curing cycle.

### Example 3

63 Parts by weight of maleimide resin (A1) obtained in Synthesis Example 5 and 35 parts by weight of 2,2′-diallyl-4,4′-sulfonyldiphenol (B1) were blended and kneaded at 150° C., and 2 parts by weight of dicumyl peroxide (C1) as a curing accelerator was then blended and kneaded at 80° C. to obtain a maleimide resin composition of the present invention. A cured sample was prepared by curing the obtained maleimide resin composition under the conditions of 180° C.×1 h and measured for the gel fraction so as to evaluate the curability. The results are shown in Tale 2.

### Examples 4 to 14 and Comparative Examples 2 and 3

Maleimide resin compositions were obtained by the same method as in Example 3 except that maleimide resin (A1), 2,2′-diallyl-4,4′-sulfonyldiphenol (B1) and dicumyl peroxide (C1) were changed to the materials/blending amounts shown in Table 2. Cured samples were prepared by curing the obtained maleimide resin compositions at 180° C.×1 h and measured for the gel fraction so as to evaluate the curability. The results are shown in Table 2.

### Gel Fraction (%):

The cured product obtained was pulverized to a size of 50 to 100 μm, and 5 g of the pulverized product was extracted by allowing it to stand in refluxing methyl ethyl ketone for about 8 hours, then dried at 80° C. for 3 hours and at 120° C. for 5 hours, and measured for the weight.

Gel fraction %=(weight (g) after methyl ethyl ketone treatment/5 g)×100

### Gel Time:

The time until gelling on an oven at 175° C. was measured.

### Transfer Moldability:

To be capable of taking out the cured resin from the mold at 175° C. within 20 minutes.

TABLE 2

| | | | | | | | Gel | Gel | |
|---|---|---|---|---|---|---|---|---|---|
| | | | | | | | Fraction | Time | Transfer |
| | Component (A) | | Component (B) | | Component (C) | | at | at | Molding |
| | | Blending | | Blending | | Blending | 180° C. | 175° C. | at |
| | Material | Amount | Material | Amount | Material | Amount | (%) | (s) | 175° C. |
| Example 3 | A1 | 63 | B1 | 35 | C1 | 2 | 99 | 40 | ∘ |
| Example 4 | A1 | 63 | B2 | 35 | C1 | 2 | 99 | 14 | ∘ |
| Example 5 | A1 | 63 | B3 | 35 | C1 | 2 | 99 | 42 | ∘ |
| Example 6 | A1 | 63 | B4 | 35 | C1 | 2 | 99 | 15 | ∘ |
| Example 7 | A2 | 76 | B5 | 22 | C1 | 2 | 99 | 32 | ∘ |
| Example 8 | A2 | 75 | B6 | 23 | C1 | 2 | 99 | 35 | ∘ |
| Example 9 | A2 | 54 | B1 | 44 | C1 | 2 | 99 | 31 | ∘ |
| Example 10 | A2 | 54 | B2 | 44 | C1 | 2 | 99 | 13 | ∘ |
| Example 11 | A2 | 54 | B3 | 44 | C1 | 2 | 99 | 34 | ∘ |
| Example 12 | A2 | 54 | B4 | 44 | C1 | 2 | 99 | 16 | ∘ |
| Example 13 | A2 | 62 | B5 | 34 | C1 | 2 | 99 | 26 | ∘ |
| Example 14 | A2 | 61 | B6 | 35 | C1 | 2 | 99 | 24 | ∘ |
| Comparative | A1 | 66 | b1 | 32 | C1 | 2 | 63 | >600 | x |
| Example 2 | | | | | | | | | |
| Comparative | A2 | 56 | b1 | 42 | C1 | 2 | 81 | >600 | x |
| Example 3 | | | | | | | | | |

A2: Maleimide compound (BMI-2300, produced by Daiwa Kasei Industry Co., Ltd.)

It is seen from Table 2 that compared with the his A-type allylphenol for comparison, the reactivity of the bis S-type alkenyl group is excellent also in maleimide resins differing in the structure and furthermore, even if possessing a substituent other than phenol, the compound has excellent reactivity.

In addition, since the gel time at 175° C. is about 30 seconds, the composition has curability comparable to that of the epoxy resin/phenol curing system and is therefore believed to be usable also in the semiconductor sealing material field requiring, among others, the speed of the curing cycle.

### Example 15

63 Parts by weight of maleimide resin (A1) obtained in Synthesis Example 5, 35 parts by weight of 2,2′-diallyl*4,4′-sulfonyldiphenol (B1), and 2 parts by weight of dicumyl peroxide (C1) as a curing accelerator were blended, kneaded by a twin roll, subjected to transfer molding at 175° C., and cured under the conditions of 200° C.×2 h to obtain a cured product. The following physical properties of the cured product obtained were evaluated. The results are shown in Table 3.

### Example 16

63 Parts by weight of maleimide resin (A1) obtained in Synthesis Example 5, 35 parts by weight of sulfonium compound (B2) obtained in Synthesis Example 1, and 2 parts by weight of dicumyl peroxide (C1) as a curing accelerator were blended, kneaded by a twin roll, subjected to transfer molding at 175° C., and cured under the conditions of 200° C.×2 h to obtain a cured product. The following physical properties of the cured product obtained were evaluated. The results are shown in Table 3.

### Example 17

64 Parts by weight of maleimide resin (A1) obtained in Synthesis Example 5 and 36 parts by weight of sulfonium compound (B32) obtained in Synthesis Example 1 were blended, kneaded by a twin roll, subjected to transfer molding at 175° C., and cured under the conditions of 200° C.×2 h to obtain a cured product. The following physical properties of the cured product obtained were evaluated. The results are shown in Table 3.

### Comparative Example 4

61 Parts of EPPN-502H (produced by Nippon Kayaku Co., Ltd., epoxy equivalent: 169 g/eq., softening point: 67.5° C. EP1), 38 parts by weight of phenol novolac (P-2, produced by Meiwa Plastic Industries, Ltd., H-1, hydroxyl equivalent: 106 g/eq.), and 1 part by weight of triphenylphosphine (TPP, JUNSEI CHEMICAL CO., LTD., reagent) were blended and uniformly mixed/kneaded using a mixing roll to obtain an epoxy resin composition. The obtained epoxy resin composition was tableted, then subjected to transfer molding to prepare a resin molded body, and cured under the conditions of 160° C.×2 h+180° C.×6 h to obtain a cured product. The following physical properties of the cured product obtained were evaluated. The results are shown in Table 3.

### Comparative Example 5

65 Parts of EOCN-1020-55 (produced by Nippon Kayaku Co., Ltd., epoxy equivalent: 194 g/eq., softening point: 54.8° C. EP2), 34 parts by weight of phenol novolac (P-2, produced by Meiwa Plastic Industries, Ltd., H-1, hydroxyl equivalent: 106 g/eq.), and 1 part by weight of TPP (JUNSEI CHEMICAL CO., LTD., reagent) were blended and uniformly mixed/kneaded using a mixing roll to obtain an epoxy resin composition. The obtained epoxy resin composition was tableted, then subjected to transfer molding to prepare a resin molded body, and cured under the conditions of 160° C.×2 h+180° C.×6 h to obtain a cured product. The following physical properties of the cured product obtained were evaluated. The results are shown in Table 3.

The following measurements of the cured products obtained were conducted.

DMA

Measured Items:
storage elastic modulus at 30° C., 200° C. and 250° C. glass transition temperature (temperature at the maximum of tan 5)

Measurement Method:
dynamic viscoelasticity meter Q-800 manufactured by TA-instruments

Measurement temperature range: from 30 to 350° C.

Temperature rise rate: 2° C./min

Specimen size: A specimen cut out into 5 mm×50 mm was used (thickness: about 800 μm).

Dielectric Constant and Dielectric Loss Tangent:

Measurement method: Measured at 1 GHz in conformity with K6991 by means of a cavity resonator manufactured by Agilent Technologies

Bending Test:

Measured items: bending strength, flexural modulus

Measurement Method:
measured at 30° C. in conformity with JIS-6481 (bending strength)

Thermal Decomposition Measurement:

Measurement method: TG-DTA6220 manufactured by S11

Measurement temperature range: from 30 to 580° C.

Temperature rise rate: 10° C./min

Td1: 1% weight loss temperature

Td5: 5% weight loss temperature

TABLE 3

| | | | Example | Example | Example | Comparative | Comparative |
|---|---|---|---|---|---|---|---|
| Evaluation test results | | | 15 | 16 | 17 | Example 4 | Example 5 |
| DMA | Tan δ | ° C. | >350 | >350 | 346 | 245.9 | 185.3 |

| | | | | | | | |
|---|---|---|---|---|---|---|---|
| DMA | 30° C. Storage elastic | Mpa | 3760 | 3825 | 3427 | 2550 | 2875 |
| | modulus | | | | | | |
| DMA | 30° C. Storage elastic | Mpa | 2743 | 2787 | 2510 | 1534 | 108 |
| | modulus | | | | | | |
| DMA | 250° C. Storage elastic | Mpa | 2003 | 2040 | 1287 | 245 | 84 |
| | modulus | | | | | | |

| Td1 | | ° C. | 334 | 315 | 311 | 298 | 300 |
|---|---|---|---|---|---|---|---|
| Td5 | | ° C. | 401.1 | 387.4 | 374 | 316.2 | 333.9 |
| Bending test | Condition: 30° C. | Mpa | 71 | 85 | 66 | 79 | 77 |
| Flexural | Condition: 30° C. | Gpa | 4.1 | 4.2 | 4.2 | 2.9 | 3.2 |
| modulus | | | | | | | |

| | | | | | | |
|---|---|---|---|---|---|---|
| Dielectric | Dielectric constant | 3.18 | 3.01 | 3.04 | 3.42 | 3.19 |
| constant | Dielectric loss tangent | 0.013 | 0.010 | 0.010 | 0.041 | 0.027 |
| (1 GHz) | | | | | | |

It is seen from Table 3 that the cured product of the maleimide resin composition of the present invention can be molded under the same curing conditions as those for the epoxy resin and furthermore, compared with the case of using a high heat-resistant epoxy resin, the cured product obtained has Tg higher by about 100° C., is excellent in the mechanical strength, high elastic modulus and low dielectric properties, and experiences little change in the elastic modulus at room temperature as well as at high temperatures.

### Example 18

63 Parts by weight of maleimide resin (A1) obtained in Synthesis Example 5, 35 parts by weight of 2,2′-diallyl-4,4′-sulfonyldiphenol (RI), and 2 parts by weight of dicumyl peroxide (C1) as a curing accelerator were dissolved in 100 parts by weight of MEK to prepare a varnish. A 0.1 mm-thick glass cloth (produced by Arisawa Manufacturing Co., Ltd., Part No. 1031, NT-105 S640) was impregnated with the prepared vanish and dried at 120° C.×5 min to prepare a prepreg. Thereafter, 20 sheets of the prepreg were sandwiched between copper foils (CF-T9LK-STD-18, manufactured by Fukuda Metal Foil & Powder Co., Ltd.) and heat-pressed under reduced pressure at a pressure of 1.0 MPa at 180° C.×2 h to prepare a 2 mm-thick copper-foiled printed circuit board, and the 90° C. peel strength of the copper foil was measured. The results are shown in Table 4.

### Comparative Example 6

63 Parts by weight of maleimide resin (A1) obtained in Synthesis Example 5 and 35 parts by weight of o,o′-diallylbisphenol A (b 1) were blended and kneaded at 150° C., 2 parts by weight of dicumyl peroxide (C1) as a curing accelerator was then added, and mixture was dissolved in 100 parts by weight of MEK to prepare a varnish. A 0.1 mm-thick glass cloth (produced by Arisawa Manufacturing Co., Ltd., Part No. 1031. NT-105 S640) was impregnated with the prepared vanish and dried at 120° C.×5 min to prepare a prepreg. Thereafter, 20 sheets of the prepreg were sandwiched between copper foils (CF-T9LK-STD-18, manufactured by Fukuda Metal Foil & Powder Co., Ltd.) and heat-pressed under reduced pressure at a pressure of 1.0 MPa at 230° C.×2 h to prepare a 2 mm-thick copper-foiled printed circuit board, and the 90° C. peel strength of the copper foil was measured. The results are shown in Table 4.

### 90° C. Peel Strength Measurement Method:

Measured in conformity with JIS C6481.

TABLE 4

| | | Example 18 | Comparative Example 6 |
|---|---|---|---|
| Peel strength | kN/m | 0.7 | 0.2 |

As seen from Table 4, it was understood that compared with his A-type allylphenol, bis S-type allylphenol has excellent copper foil adhesion and is therefore an excellent adhesive.

### Example 19

63 Parts by weight of maleimide resin (A1) obtained in Synthesis Example 5, 35 parts by weight of 2,2′-diallyl-4,4′-sulfonyldiphenol (B1), and 2 parts by weight of dicumyl peroxide (C1) as a curing accelerator were blended, kneaded by a twin roll, and uniformly mixed/kneaded using a mixing roll to obtain a maleimide resin composition. The maleimide resin composition obtained was pulverized by means of a mixer and furthermore tableted by a tableting machine. The resulting tableted maleimide resin composition was subjected to transfer molding (175° C.×60 seconds) and further to transfer molding at 175° C. and then cured under the conditions of 200° C.×2 h to prepare a cured sample, thereby obtaining a specimen for evaluation. A flame retardancy test was performed under the following measurement conditions. The evaluation results are also shown in Table 5.

### Example 20

54 Parts by weight of maleimide compound (BM1-2300, produced by Daiwa Kasei Industry Co., Ltd.) and 44 parts by weight of sulfonium compound (B3) obtained in Synthesis Example 2 were blended, 2 parts by weight of dicumyl peroxide (C1) as a curing accelerator was also blended, and the mixture was kneaded by a twin roll and uniformly mixed/kneaded using a mixing roll to obtain a maleimide resin composition. The maleimide resin composition obtained was pulverized by means of a mixer and furthermore tableted by a tableting machine. The resulting tableted maleimide resin composition was subjected to transfer molding (175° C.×60 seconds) and further to transfer molding at 175° C. and then cured under the conditions of 200° C.×2 h to prepare a cured sample, thereby obtaining a specimen for evaluation. A flame retardancy test was performed under the following measurement conditions. The evaluation results are also shown in Table 5.

### Example 21

56 Parts by weight of maleimide compound (BM1-1000, produced by Daiwa Kasei Industry Co., Ltd.) and 42 parts by weight of sulfonium compound (B3) obtained in Synthesis Example 2 were blended, 2 parts by weight of dicumyl peroxide (C1) as a curing accelerator was also blended, and the mixture was kneaded by a twin roll and uniformly mixed/kneaded using a mixing roll to obtain a maleimide resin composition. The maleimide resin composition obtained was pulverized by means of a mixer and furthermore tableted by a tableting machine. The resulting tableted maleimide resin composition was subjected to transfer molding (175° C.×60 seconds) and further to transfer molding at 175° C. and then cured under the conditions of 200° C.×2 h to prepare a cured sample, thereby obtaining a specimen for evaluation. A flame retardancy test was performed under the following measurement conditions. The evaluation results are also shown in Table 5.

### Comparative Example 7

63 Parts by weight of maleimide resin (A1) obtained in Synthesis Example 5 and 35 parts by weight of o,o′-diallylbisphenol A (b1) were blended, 2 parts by weight of dicumyl peroxide (C1) as a curing accelerator was also blended, and the mixture was kneaded by a twin roll and uniformly mixed/kneaded using a mixing roll to obtain a maleimide resin composition. The maleimide resin composition obtained was pulverized by means of a mixer and furthermore tableted by a tableting machine. The resulting tableted maleimide resin composition was subjected to transfer molding (175° C.×60 seconds) and further to transfer molding at 175° C. and then cured under the conditions of 200° C.×2 h to prepare a cured sample, thereby obtaining a specimen for evaluation. A flame retardancy test was performed under the following measurement conditions. The evaluation results are also shown in Table 5.

### Flame Retardancy Test

Flame Retardancy

The test was performed in conformity with UL94. However, the test was performed by employing a sample size of 12.5 mm (width)×150 mm (length) and a thickness of 0.8 mm.

Afterflame Time:

The total of afterflame times after one set consisting of 5 samples was exposed to flame contact 10 times.

TABLE 5

| | | Example | Example | Example | Comparative |
|---|---|---|---|---|---|
| | | 19 | 20 | 21 | Example 7 |
| Flame retardancy | | V-0 | V-0 | V-0 | burned down |
| Flame retardant time | s | 21 | 28 | 31 | 156 |

As seen from Table 5, it was understood that compared with bis A-type allylphenol, his S-type allylphenol exhibits excellent flame retardancy. It is apparent that the compound exhibits flame retardancy even without using a flame retardant such as halogen or antimony compound.

### Example 22

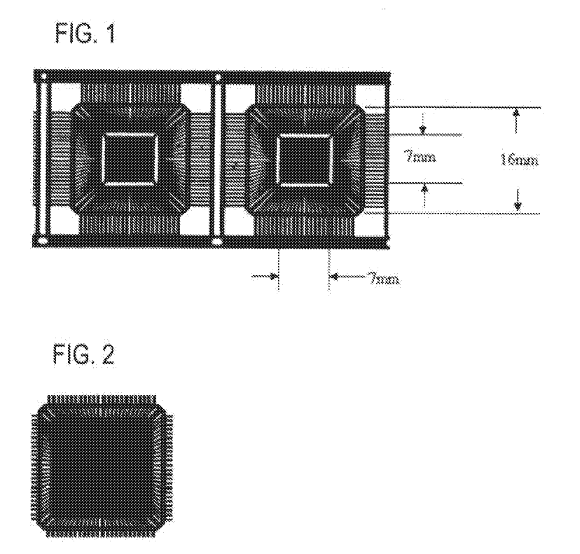

Using the maleimide resin composition of Example 18, a 96-Pin QFP (chip size: 7×7×0.1 mm (thickness), package size: 14×14×1.35 mm (thickness)) lead frame (manufactured by Kenseido, Co.: special order from Nippon Kayaku Co., Ltd.) illustrated in FIG. 1 was prepared. First, the lead frame was set in a transfer molding die, and a maleimide resin composition tableted in the same manner as above was subjected to transfer molding (175° C.×60 seconds), demolded, and then cured under the conditions of 180° C.×2 hours to prepare a sealant of 96-Pin QFP (FIG. 2).

It can be confirmed from Example 22 that the maleimide resin composition of the present invention seals a lead frame in the same curing process as that of the conventional epoxy resin composition, etc. This reveals that the composition can be applied to a semiconductor sealing material.

While the invention has been described in detail and with reference to specific embodiments thereof, it will be apparent to one skilled in the art that various changes and modifications can be made therein without departing from the spirit and scope of the invention.

This application is based on Japanese Patent Application (Patent Application No. 2016-154824) filed on Aug. 5, 2016, the entirety of which are incorporated herein by way of reference. In addition, all references cited herein are incorporated in their entirety herein.

### INDUSTRIAL APPLICABILITY

The maleimide resin composition, prepreg and cured product thereof of the present invention can be used for highly reliable semiconductor sealing material application, electric/electronic component insulating material application, various composite material applications including a laminated board (printed-wiring glass fiber-reinforced composite material) and CFRP (carbon fiber-reinforced composite material), various adhesive applications, various coating material applications, structural members, etc.

1. A maleimide resin composition, comprising:
a maleimide compound (A) and a sulfonyl compound (B) containing, in the molecule, a structure represented by the following formula (1): 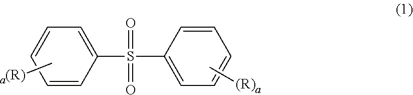
wherein each of the plurality of R's independently represents an alkenyl group, an alkenyl ether group, a hydrogen atom, a halogen atom, an alkyl group having a carbon number of 1 to 10, a fluoroalkyl group having a carbon number of 1 to 4, a hydroxyl group, an allyloxy group, an amino group, a cyano group, a nitro group, an acyl group, an acyloxy group, a carboxyl group, a tertiary carbon structure-containing group, a cyclic alkyl group, or a glycidyl group; at least one R is an alkenyl group or an alkenyl ether group; and a represents an integer of 1 to 4.

2. The maleimide resin composition according to claim 1,
wherein the maleimide compound (A) is at least one compound selected from the group consisting of an aromatic maleimide compound and an aliphatic maleimide compound.

3. The maleimide resin composition according to claim 1,
wherein the sulfonyl compound (B) is a sulfonyl compound represented by the following formula (2): 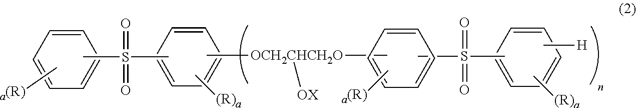
wherein each of the plurality of R's independently represents an alkenyl group, an alkenyl ether group, a hydrogen atom, a halogen atom, an alkyl group having a carbon number of 1 to 10, a fluoroalkyl group having a carbon number of 1 to 4, a hydroxyl group, an allyloxy group, an amino group, a cyano group, a nitro group, an acyl group, an acyloxy group, a carboxyl group, a tertiary carbon structure-containing group, a cyclic alkyl group, or a glycidyl group; at least one R is an alkenyl group or an alkenyl ether group; each X independently represents a hydrogen atom or a glycidyl group; a represents an integer of 1 to 4; and n is from 0 to 10, and the average value thereof represents a real number of 0 to 10.

4. The maleimide resin composition according to claim 1, further comprising a radical polymerization initiator (C).

5. The maleimide resin composition according to claim 4,
wherein the radical polymerization initiator (C) is at least one initiator selected from the group consisting of an organic peroxide and an azo compound.

6. A prepreg, which holds the maleimide resin composition according to claim 1 on a sheet-like fiber base material and is in a semi-cured state.

7. A cured product of the maleimide resin composition according to claim 1.

8. A cured product of the prepreg according to claim 6.

9. A semiconductor device, which is sealed using the maleimide resin composition according to claim 1.
